(19) United States
(12) Patent Application Publication
(10) Pub. No.: US 2026/0231403 A1
(43) Pub. Date: Aug. 6, 2026

(54) SEMICONDUCTOR DEVICE

(71) Applicant: SK hynix Inc., Gyeonggi-do (KR)

(72) Inventors: Seok Min CHOI, Gyeonggi-do (KR); Jung Shik JANG, Gyeonggi-do (KR); Rho Gyu KWAK, Gyeonggi-do (KR); Mi Seong PARK, Gyeonggi-do (KR); Na Yeong YANG, Gyeonggi-do (KR); Won Geun CHOI, Gyeonggi-do (KR)

(21) Appl. No.: 19/212,676

(22) Filed: May 20, 2025

(30) Foreign Application Priority Data
Feb. 6, 2025 (KR) 10-2025-0014956

(51) Int. Cl. H10B 41/27; H10B 41/10; H10B 41/35; H10B 43/10; H10B 43/27; H10B 43/35

(52) U.S. Cl. CPC H10B 41/27; H10B 41/10; H10B 41/35; H10B 43/10; H10B 43/27; H10B 43/35

(57) ABSTRACT

A semiconductor device includes: a gate structure including first to n-th conductive layers which are sequentially stacked and extending in a first direction, n being an integer of 2 or more; first to m−1-th slit structures extending in the first direction through the gate structure and separating each of the first to n-th conductive layers into first to m-th gate lines, m being an integer of 2 or more; and first to m-th contact plugs respectively connected to the first to m-th gate lines, wherein at least one of the first to m−1-th slit structures includes a bending portion partially surrounding at least two contact plugs connected to gate lines of different conductive layers, among the first to m-th contact plugs.

### CROSS-REFERENCE TO RELATED APPLICATION

This application claims priority under 35 U.S.C. § 119 to Korean Patent Application No. 10-2025-0014956 filed on Feb. 6, 2025, which is incorporated herein by reference in its entirety.

### BACKGROUND

### 1. Technical Field

Embodiments of the present disclosure relate to an electronic device, and more particularly, to a semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate approaches a limit, three-dimensional (3D) semiconductor devices for stacking memory cells on a substrate have been proposed. Furthermore, in order to improve the operational reliability of such 3D semiconductor devices, various structures and manufacturing methods have been developed.

### SUMMARY

In an embodiment, a semiconductor device may include: a gate structure including first to n-th conductive layers which are sequentially stacked and extending in a first direction, n being an integer of 2 or more; first to m-1-th slit structures extending in the first direction through the gate structure and separating each of the first to n-th conductive layers into first to m-th gate lines, m being an integer of 2 or more; and first to m-th contact plugs respectively connected to the first to m-th gate lines, wherein at least one of the first to m-1-th slit structures may include a bending portion partially surrounding at least two contact plugs connected to gate lines of different conductive layers, among the first to m-th contact plugs.

In an embodiment, a semiconductor device may include: a first gate structure including first gate lines stacked in a staircase shape, each of the first gate lines including first line portions extending in a first direction and first pad portions having a greater width than the first line portions, and the first line portions and the first pad portions being alternately arranged; and a second gate structure adjacent to the first gate structure in a second direction intersecting with the first direction, the second gate structure including second gate lines stacked in a staircase shape, each of the second gate lines including second line portions extending in the first direction and second pad portions having a greater width than the second line portions, and the second line portions and the second pad portions being alternately arranged, wherein the first line portions and the second pad portions may face each other in the second direction, and the second line portions and the first pad portions may face each other in the second direction.

In an embodiment, a semiconductor device may include: a first gate structure including first gate lines stacked in a staircase shape, each of the first gate lines including first line portions extending in a first direction and first pad portions having a greater width than the first line portions, and the first line portions and the first pad portions being alternately arranged; a second gate structure adjacent to the first gate structure in a second direction intersecting with the first direction, the second gate structure including second gate lines stacked in a staircase shape, each of the second gate lines including second line portions extending in the first direction and second pad portions surrounding the first pad portions, and the second line portions and the second pad portions being alternately arranged; first contact plugs respectively connected to first pad portions located at ends of the first gate lines; and second contact plugs respectively connected to second pad portions located at ends of the second gate lines.

### BRIEF DESCRIPTION OF THE DRAWINGS

FIGS. 1A to 1D are diagrams illustrating the structure of a semiconductor device in accordance with an embodiment.

FIGS. 2A and 2B are diagrams illustrating the structure of a semiconductor device in accordance with an embodiment.

FIGS. 3A to 3E are diagrams illustrating the structure of a semiconductor device in accordance with an embodiment.

FIGS. 4A and 4B are diagrams illustrating the structure of a semiconductor device in accordance with an embodiment.

FIGS. 5A and 5B are diagrams illustrating the structure of a semiconductor device in accordance with an embodiment.

FIGS. 6A and 6B are diagrams illustrating the structure of a semiconductor device in accordance with an embodiment.

FIG. 7 is a diagram illustrating the structure of a semiconductor device in accordance with an embodiment.

FIG. 8 is a diagram illustrating the structure of a semiconductor device in accordance with an embodiment.

FIG. 9 is a configuration diagram of a semiconductor device in accordance with an embodiment.

FIG. 10 is a configuration diagram of a semiconductor device in accordance with an embodiment.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

The following embodiments are directed to a semiconductor device having a stable structure and improved characteristics.

By stacking memory cells in three dimensions, the embodiments disclosed herein improve the degree of integration of a semiconductor device. The embodiments also provide a semiconductor device having a stable structure and improved reliability.

Hereafter, embodiments in accordance with the technical spirit of the present disclosure will be described with reference to the accompanying drawings.

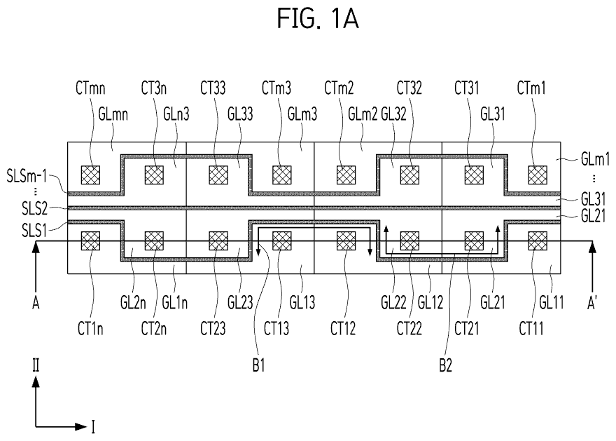

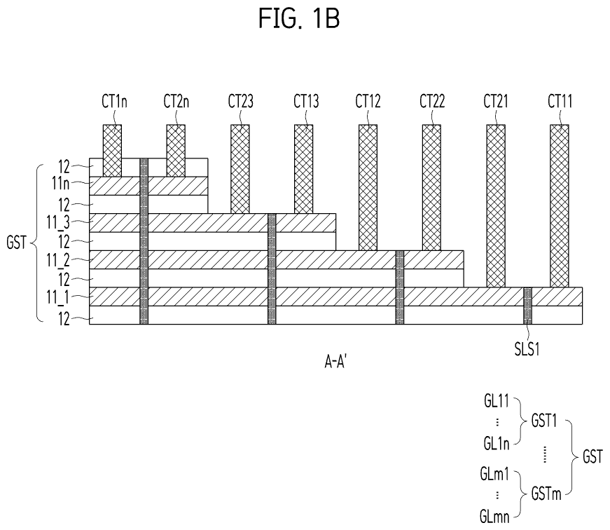

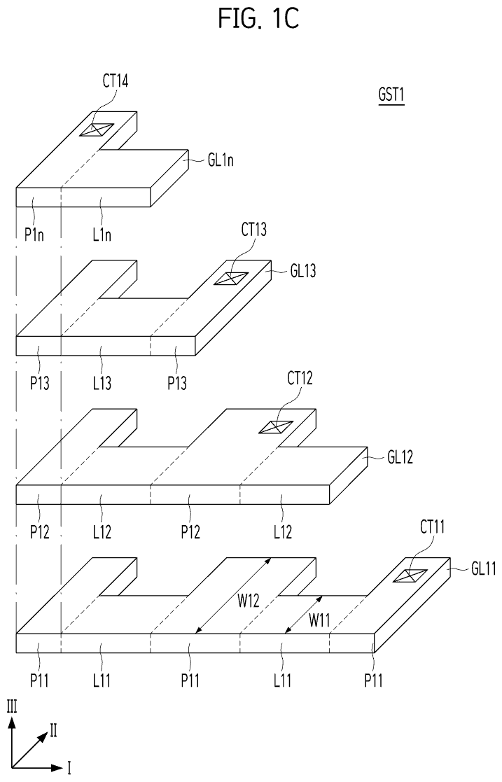

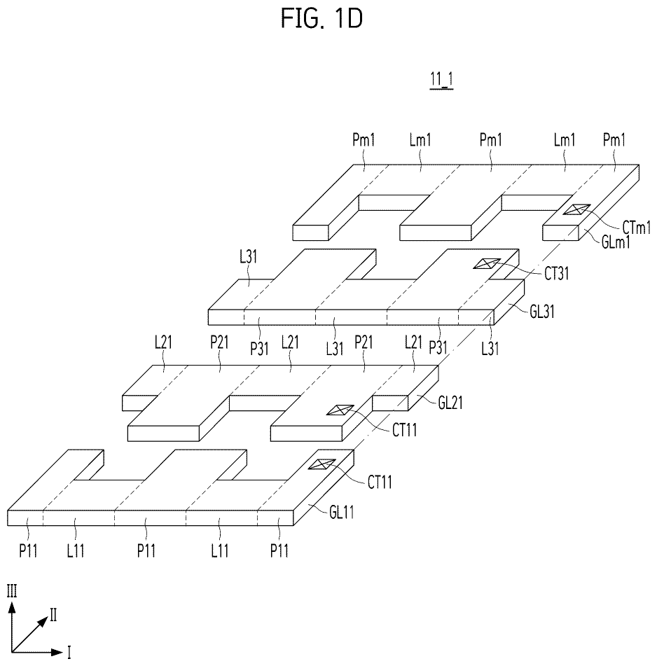

FIGS. 1A to 1D are diagrams illustrating the structure of a semiconductor device in accordance with an embodiment. FIG. 1A is a plan view, and FIG. 1B is a cross-sectional view taken along line A-A′ of FIG. 1A.

Referring to FIGS. 1A and 1B, the semiconductor device may include a gate structure GST, slit structures SLS1 to SLSm-1, and contact plugs CT11 to CTmn (going right to left, bottom to top). The gate structure GST may extend in a first direction I, and may include first to n-th conductive layers 11_1 to 11_n stacked in a staircase shape of n layers. Here, n may be an integer of 2 or more. As an example, the gate structure GST may include conductive layers 11_1 to 11_n and insulating layers 12 that are alternately stacked.

The slit structure SLS1 to SLSm-1 may extend in the first direction I through the gate structure GST. The slit structures SLS1 to SLSm-1 may separate each of the first to n-th conductive layers 11_1 to 11_n into first to m-th gate lines GL11 to GLmn. Here, m may be an integer of 2 or more, and may be an even number. In other words, the ending alphanumeric characters in each element identifier may each correspond to a coordinate on a row, grid, layer, or element. For example, for GL11, the last two digits 1 and 1 may correspond to position 1 in a first direction and position 1 in a second direction. Therefore, GL11 should not be interpreted as GL eleven but rather as GL one-one. The first to m-th gate lines GL11 to GLmn may be source select lines or drain select lines. As an example, the first to m-th gate lines GL11 to GLmn may be drain select lines, and the gate structure GST may be a DSL stack.

The gate structure GST may include a first gate structure GST1 to an m-th gate structure GSTm separated by first to m−1-th (i.e., m minus 1) slit structures SLS1 to SLSm-1. The first to m-th gate structures GST1 to GSTm may be adjacent to each other in a second direction II intersecting with the first direction I. The first gate structure GST1 may include first gate lines GL11 to GL1n, the second gate structure GST2 may include second gate lines GL21 to GL2n, the third gate structure GST3 may include third gate lines GL31 to GL3n, and the m-th gate structure GSTm may include m-th gate lines GLm1 to GLmn.

The contact plugs CT11 to CTmn may be connected to the gate lines GL11 to GLmn, respectively. First to m-th contact plugs CT11 to CTm1 may be connected to the first to m-th gate lines GL11 to GLm1, respectively, first to m-th contact plugs CT12 to CTm2 may be connected to the first to m-th gate lines GL12 to GLm2, respectively, first to m-th contact plugs CT13 to CTm3 may be connected to the first to m-th gate lines GL13 to GLm3, respectively, and first to m-th contact plugs CT1n to CTmn may be connected to the first to m-th gate lines GL1n to GLmn, respectively.

The first to m-th contact plugs CT11 to CTmn connected to the same conductive layers 11_1 to 11_n may be located at vertices of a polygon with m sides (for example, an m-gon), respectively. As an example, the first conductive layer 11_1 may include first to fourth gate lines GL11 to GL41, and first to fourth contact plugs CT11 to CT41 respectively connected to the first to fourth gate lines GL11 to GL41 may be located at vertices of a quadrangle, respectively. The first contact plug CT11 and the fourth contact plug CT41 may be adjacent to each other in the second direction II, and the second contact plug CT21 and the third contact plug CT31 may be adjacent to each other in the second direction II.

The first to m-th contact plugs CT11 to CTmn may be arranged in the first direction I and the second direction II. As an example, the first and second contact plugs CT11 to CT1n and CT21 to CT2n respectively connected to the first and second gate structures GST1 and GST2 may be arranged in a row along the first direction I. The first contact plugs CT11 to CT1n and the second contact plugs CT21 to CT2n may be alternately arranged in units of two. The third and fourth contact plugs CT31 to CT3n and CT41 to CT4n respectively connected to the third and fourth gate structures GST3 and GST4 may be arranged in a row along the first direction I. The third contact plugs CT31 to CT3n and the fourth contact plugs CT41 to CT4n may be alternately arranged in units of two. The second contact plugs CT21 to CT2n connected to the second gate structure GST2 and the third contact plugs CT31 to CT3n connected to the third gate structure GST3 may be adjacent to each other in the second direction II.

The first to m−1-th slit structures SLS1 to SLSm-1 may extend between the first to m-th contact plugs CT11 to CTmn connected to the same conductive layers 11_1 to 11_n. As an example, the first slit structure SLS1 may extend between the first contact plug CT11 and the second contact plug CT21 adjacent to each other in the first direction I. The third slit structure SLS3 may extend between the third contact plug CT31 and the fourth contact plug CT41 adjacent to each other in the first direction I. The first to third slit structures SLS1 to SLS3 (where, for example, m=4 and m−1=3 and SLSm-1 shown in FIG. 1A corresponds to SLS3) may extend between the first contact plug CT11 and the fourth contact plug CT41 (shown as CTm1 in FIG. 1A, where m=4) adjacent to each other in the second direction II. The second slit structure SLS2 may extend between the second contact plug CT21 and the third contact plug CT31 adjacent to each other in the second direction II.

At least one of the first to m−1-th slit structures SLS1 to SLSm-1 may include bending portions B1 and B2 surrounding the contact plugs CT11 to CTmn connected to the gate lines GL11 to GLmn of different layers. A first bending portion B1 may extend in the second direction II, and a second bending portion B2 may extend in a direction opposite to the second direction II. In a plane defined by the first direction I and the second direction II, the first bending portion B1 may have a C shape of which one side is opened, and the second bending portion B2 may have a C shape of which the other side is opened. Two contact plugs CT12 and CT13 surrounded by the first bending portion B1 may be connected to different gate lines GL12 and GL13, respectively, and may be adjacent to each other in the first direction I.

Odd slit structures SLS1 and SLS3 of the first to m−1-th slit structures SLS1 to SLSm-1 may each include the bending portions B1 and B2. Even slit structures SLS2 and SLS4 of the first to m−1-th slit structures SLS1 to SLSm-1 might not include the bending portions, and may each have a straight shape. As an example, the first slit structure SLS1 and the third slit structure SLS3 may each include the bending portions B1 and B2, and may have a symmetrical shape based on the second slit structure SLS2.

Referring to FIG. 1C, the first gate structure GST1 may include first gate lines GL11 to GL1n stacked in a staircase shape of n layers. The first gate lines GL11 to GL1n may be stacked in a third direction III. The third direction III may be perpendicular to the first direction I and the second direction II.

The first gate line GL11 of a first layer may include first line portions L11 extending in the first direction I and first pad portions P11 having a greater width than the first line portions L11. As an example, the first line portion L11 may have a first width W11, and the first pad portion P11 may have a second width W12 greater than the first width W11. The first line portions L11 and the first pad portions P11 may be alternately arranged. The first gate line GL12 of a second layer may include first line portions L12 extending in the first direction I and first pad portions P12 having a greater width than the first line portions L12, and the first line portions L12 and the first pad portions P12 may be alternately arranged. The first gate line GL13 of a third layer may include a first line portion L13 extending in the first direction I and first pad portions P13 having a greater width than the first line portion L13, and the first line portion L13 and the first pad portions P13 may be alternately arranged. The first gate line GL1n of an n-th layer may include a first line portion L1n extending in the first direction I and a first pad portion P1n having a greater width than the first line portion L1n. The first pad portions P11 to P1n may have substantially the same width in the second direction II.

Referring to FIG. 1D, the first conductive layer 11_1 may include first to m-th gate lines GL11 to GLm1. The first to m-th gate lines GL11 to GLm1 may be located at the same layer (e.g., the first layer), and may be arranged in the second direction II.

The first gate line GL11 may include first line portions L11 extending in the first direction I and first pad portions P11 having a greater width than the first line portions L11, and the first line portions L11 and the first pad portions P11 may be alternately arranged. The second gate line GL21 may include second line portion L21 extending in the first direction I and second pad portions P21 having a greater width than the second line portions L21, and the second line portions L21 and the second pad portions P21 may be alternately arranged. The third gate line GL31 may include third line portions L31 extending in the first direction I and third pad portions P31 having a greater width than the third line portions L31, and the third line portions L31 and the third pad portions P31 may be alternately arranged. The m-th gate line GLm1 may include m-th line portions Lm1 extending in the first direction I and m-th pad portions Pm1 having a greater width than the m-th line portions Lm1, and the m-th line portions Lm1 and the m-th pad portions Pm1 may be alternately arranged.

The first pad portion P11 and the second line portion L21 may face each other in the second direction II, the first line portion L11 and the second pad portion P21 may face each other in the second direction II, the third pad portion P31 and the fourth line portion L41 may face each other in the second direction II, and the third line portion L31 and the fourth pad portion P41 may face each other in the second direction II.

The first contact plug CT11 may be connected to a first pad portion P11 located at an end among the first pad portions P11 included in the first gate line GL11. The first pad portion P11 located at the end may be a real pad, and the remaining first pad portions P11 may be dummy pads. The second contact plug CT21 may be connected to a second pad portion P21 located at an end among the second pad portions P21 included in the second gate line GL21. The second pad portion P21 located at the end may be a real pad, and the remaining second pad portions P21 may be dummy pads. The third contact plug CT31 may be connected to a third pad portion P31 located at an end among the third pad portions P31 included in the third gate line GL31. The third pad portion P31 located at the end may be a real pad, and the remaining third pad portions P31 may be dummy pads. The m-th contact plug CTm1 may be connected to an m-th pad portion Pm1 located at an end among the m-th pad portions Pm1 included in the m-th gate line GLm1. The m-th pad portion Pm1 located at the end may be a real pad, and the remaining m-th pad portions Pm1 may be dummy pads.

According to the structure described above, because the slit structure SLS1 includes the bending portions, the first pad portion P11 may have a sufficient area between the slit structures SLS1. Accordingly, it is possible to increase a width of the pad portion in the second direction II without increasing a width of the gate structure GST in the second direction II.

The contact plugs CT11 to CTmn may be arranged in the first direction I, and the gate lines GL11 to GLmn may have a symmetrical shape. Accordingly, it is possible to secure a process margin, and it is possible to increase a program/read speed while maintaining the conductivity of the gate lines GL11 to GLmn.

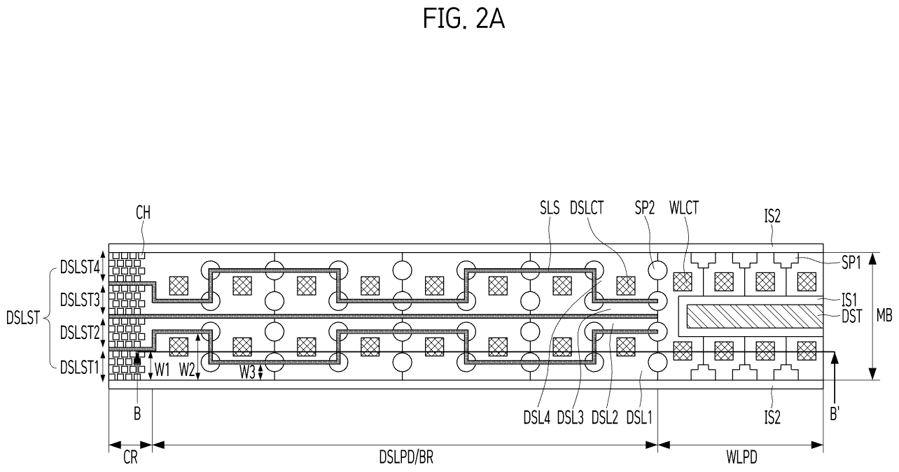

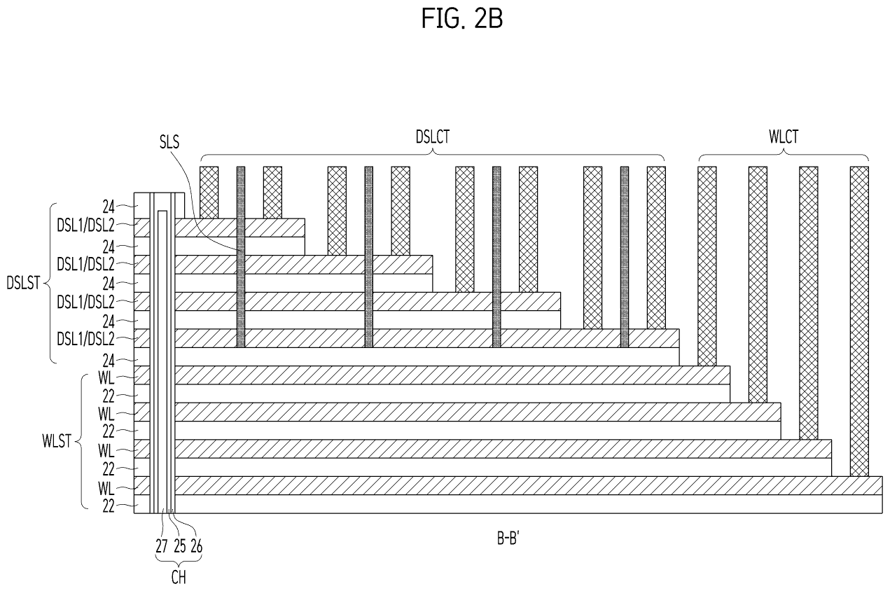

FIGS. 2A and 2B are diagrams illustrating the structure of a semiconductor device in accordance with an embodiment. FIG. 2A is a plan view, and FIG. 2B is a cross-sectional view taken along line B-B′ of FIG. 2A. Hereinafter, the content overlapping with the previously described content may be omitted.

Referring to FIGS. 2A and 2B, the semiconductor device may include a word line stack WLST, a DSL stack DSLST, a slit structure SLS, a DSL contact plug DSLCT, a channel structure CH, a first support SP1, a second support SP2, a first isolation structure IS1, a second isolation structure IS2, a word line contact plug WLCT, and a dummy stack DST.

The word line stack WLST may include word lines WL and insulating layers 22 that are alternately stacked. The word line stack WLST may include a cell region CR, a buffer region BR, and a word line pad region WLPD. The cell region CR is a region where memory cells are stacked. The word line pad region WLPD is a region where pad portions for applying driving bias to the stacked word lines WL are located, and the word line stack WLST may have a staircase shape in the word line pad region WLPD. The buffer region BR is used to connect the cell region CR and the word line pad region WLPD to each other, and may be located between the cell region CR and the word line pad region WLPD.

The DSL stack DSLST may be located above the word line stack WLST, and may include drain select lines DSL1 to DSL4 and insulating layers 24 that are alternately stacked. The DSL stack DSLST may include a cell region CR and a DSL pad region DSLPD. The cell region CR is a region where drain select transistors are stacked. The DSL pad region DSLPD is a region where pad portions for applying driving bias to the stacked drain select lines DSL1 to DSL4 are located, and the DSL stack DSLST may have a staircase shape in the DSL pad region DSLPD. The buffer region BR may be located below the DSL pad region DSLPD.

The channel structures CH may be located in the cell region CR, and may extend through the word line stack WLST and the DSL stack DSLST. The channel structure CH may include a channel layer 25, a memory layer 26 surrounding the channel layer 25, and an insulating core 27 located in the channel layer 25. The drain select transistors may be located in regions where the channel structures CH and the drain select lines DSL1 to DSL4 intersect each other, and the memory cells may be located in regions where the channel structures CH and the word lines WL intersect each other.

The DSL stack DSLST may be separated into a first DSL stack DSLST1, a second DSL stack DSLST2, a third DSL stack DSLST3, and a fourth DSL stack DSLST4 by the slit structures SLS. The first DSL stack DSLST1 may include first drain select lines DSL1 stacked in a staircase shape, the second DSL stack DSLST2 may include second drain select lines DSL2 stacked in a staircase shape, the third DSL stack DSLST3 may include third drain select lines DSL3 stacked in a staircase shape, and the fourth DSL stack DSLST may include fourth drain select lines DSL4 stacked in a staircase shape. The DSL contact plugs DSLCT may be connected to the first to fourth drain select lines DSL1 to DSL4, respectively, in the DSL pad region DSLPD.

Each of the first to fourth drain select lines DSL1 to DSL4 may have a first width W1 in the cell region CR, a second width W2 in a pad portion, and a third width W3 in a line portion. The first width W1 may be greater than the third width W3, and the second width W2 may be greater than the first width W1.

The word line contact plugs WLCT may be connected to the word lines WL, respectively, in the word line pad region WLPD. The dummy stack DST may include first insulating layers and second insulating layers that are alternately stacked. The first isolation structure IS1 may be located in the word line pad region WLPD, and may surround the dummy stack DST. The second isolation structure IS2 may extend from the cell region CR to the word line pad region WLPD via the DSL pad region DSLPD. The slit structure SLS may extend from the cell region CR to the DSL pad region DSLPD, and might not be located in the word line pad region WLPD.

The first supports SP1 may be located in the word line pad region WLPD, and may be located between the word line contact plugs WLCT. The second supports SP2 may be located in the DSL pad region DSLPD, and may be located between the DSL contact plugs DSLCT. The first supports SP1 and the second supports SP2 may have the same shape or different shapes.

According to the structure described above, because the slit structure SLS includes a bending portion, the pad portion located between the slit structures SLS may have a sufficient area, and a distance between the drain select line contact plug DSLCT and the second support SP2 may be secured. Because the slit structure SLS includes the bending portion, the drain select lines DSL1 to DSL4 may have different widths depending on regions. The drain select lines DSL1 to DSL4 may have the first width W1 in the cell region CR, and may have the second width W2 greater than the first width W1 in the pad portion. Accordingly, an area where the DSL contact plug DSLCT is to be formed may be secured (for example, acquired, delineated, etc.). Because a width of the pad portion increases to the second width W2 but a width of the line portion decreases to the third width W3, a contact area may be secured without increasing a pitch of a memory block MB.

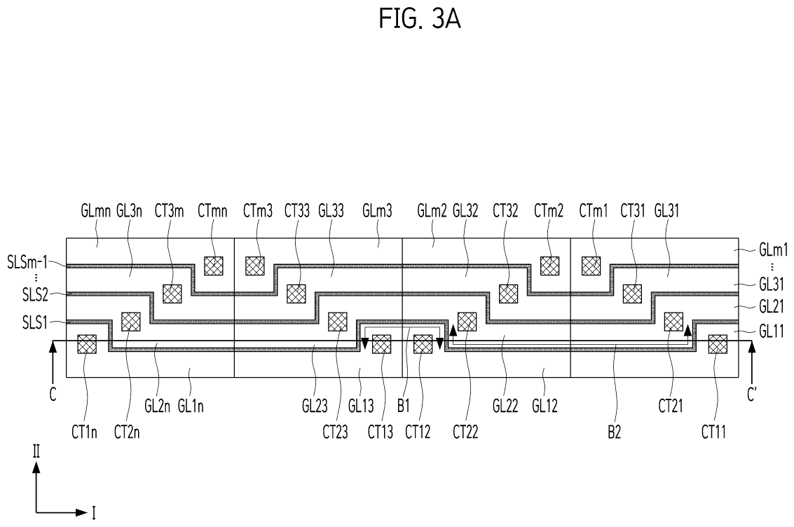

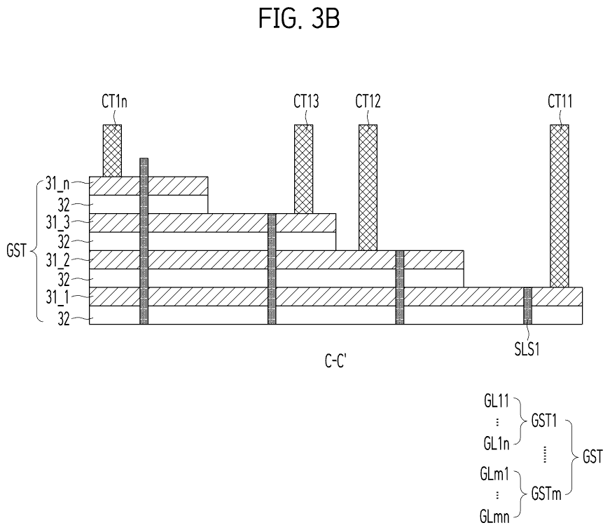

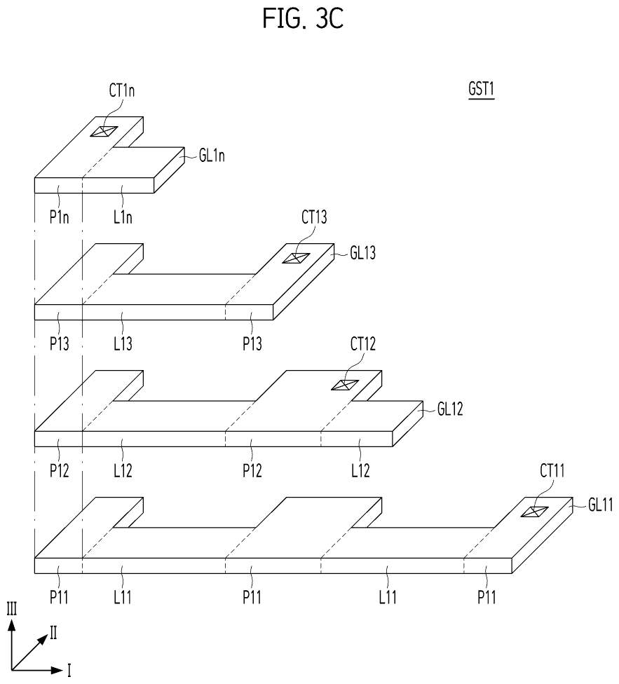

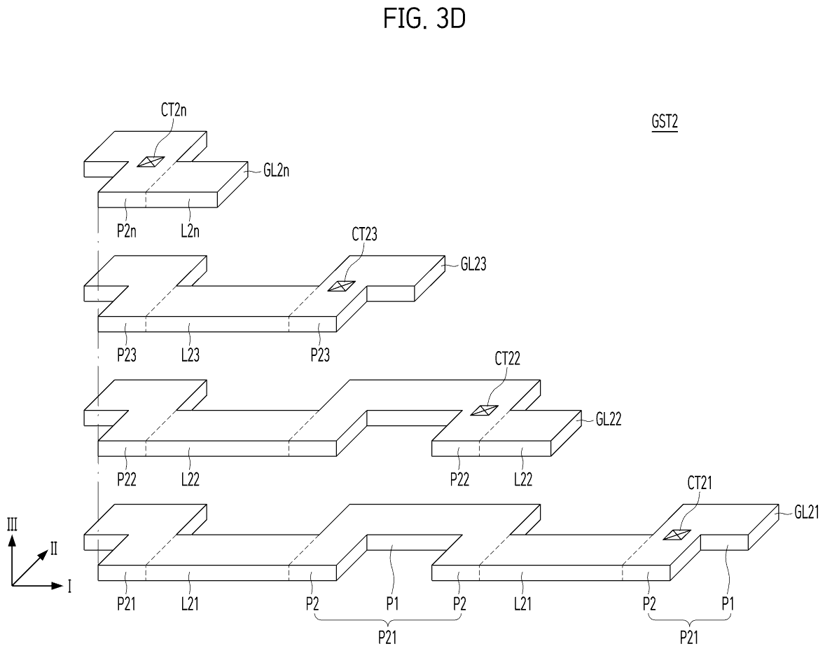

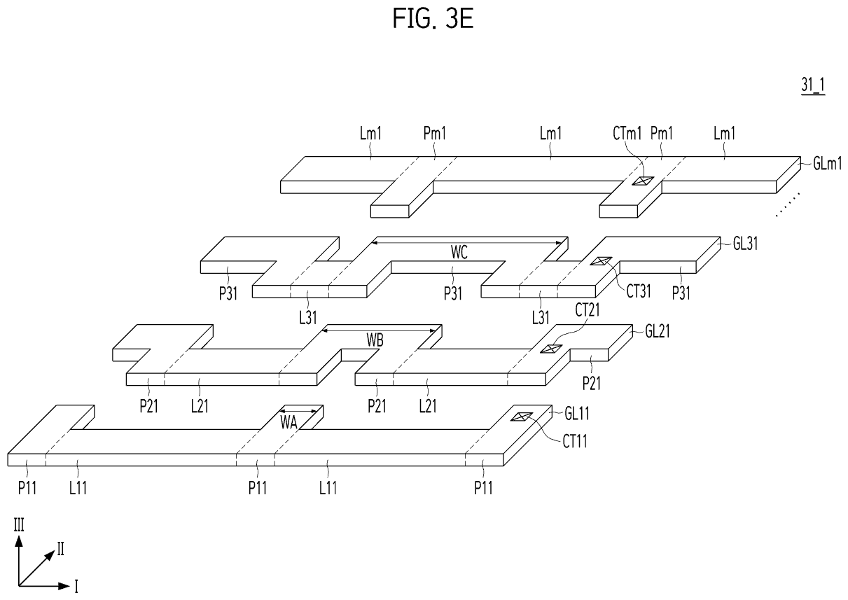

FIGS. 3A to 3E are diagrams illustrating the structure of a semiconductor device in accordance with an embodiment. FIG. 3A is a plan view, and FIG. 3B is a cross-sectional view taken along line C-C′ of FIG. 3A.

Referring to FIGS. 3A and 3B, the semiconductor device may include a gate structure GST, slit structures SLS1 to SLSm-1, and contact plugs CT11 to CTmn.

The gate structure GST may extend in the first direction I, and may include first to n-th conductive layers 31_1 to 31_n stacked in a staircase shape of n layers. Here, n may be an integer of 2 or more. As an example, the gate structure GST may include conductive layers 31_1 to 31_n and insulating layers 32 that are alternately stacked.

The slit structure SLS1 to SLSm-1 may extend in the first direction I through the gate structure GST. The slit structures SLS1 to SLSm-1 may separate each of the first to n-th conductive layers 31_1 to 31_n into first to m-th gate lines GL11 to GLmn. Here, m may be an integer of 2 or more, and may be an even number. The first to m-th gate lines GL11 to GLmn may be source select lines or drain select lines. As an example, the first to m-th gate lines GL11 to GLmn may be drain select lines, and the gate structure GST may be a DSL stack.

The gate structure GST may include a first gate structure GST1 to an m-th gate structure GSTm separated by first to m−1-th slit structures SLS1 to SLSm-1. The first to m-th gate structures GST1 to GSTm may be adjacent to each other in the second direction II. The first gate structure GST1 may include first gate lines GL11 to GL1n, the second gate structure GST2 may include second gate lines GL21 to GL2n, the third gate structure GST3 may include third gate lines GL31 to GL3n, and the m-th gate structure GSTm may include m-th gate lines GLm1 to GLmn.

The contact plugs CT11 to CTmn may be connected to the gate lines GL11 to GLmn, respectively. At a first layer, first to m-th contact plugs CT11 to CTm1 may be connected to the first to m-th gate lines GL11 to GLm1, respectively. At a second layer, first to m-th contact plugs CT12 to CTm2 may be connected to the first to m-th gate lines GL12 to GLm2, respectively. At a third layer, first to m-th contact plugs CT13 to CTm3 may be connected to the first to m-th gate lines GL13 to GLm3, respectively. At an n-th layer, first to m-th contact plugs CT1n to CTmn may be connected to the first to m-th gate lines GL1n to GLmn, respectively.

The first to m-th contact plugs CT11 to CTmn connected to the same conductive layers 31_1 to 11_n may be arranged in diagonal directions. As an example, the first to fourth contact plugs CT11 to CT41 respectively connected to the first to fourth gate lines GL11 to GL41 of the first conductive layer 31_1 may be arranged in a first diagonal direction intersecting with the first direction I and the second direction II. The first to fourth contact plugs CT12 to CT42 respectively connected to the first to fourth gate lines GL12 to GL42 of the second conductive layer 31_2 may be arranged in a second diagonal direction intersecting with the first diagonal direction. The first to m-th contact plugs CT11 to CTmn may be arranged in a wave shape or a zigzag shape extending in the first direction I.

The first to m−1-th slit structures SLS1 to SLSm-1 may extend between the first to m-th contact plugs CT11 to CTmn connected to the same conductive layers 31_1 to 31_n. As an example, the first slit structure SLS1 may extend between the first contact plug CT11 and the second contact plug CT21 adjacent to each other in the first diagonal direction. The second slit structure SLS2 may extend between the second contact plug CT21 and the third contact plug CT31 adjacent to each other in the first diagonal direction. The third slit structure SLS3 may extend between the third contact plug CT31 and the fourth contact plug CT41 adjacent to each other in the first diagonal direction.

The first to m−1-th slit structures SLS1 to SLSm-1 may include bending portions B1 and B2 surrounding the contact plugs CT11 to CTmn connected to the gate lines GL11 to GLmn of different layers. A first bending portion B1 may extend in the second direction II, and a second bending portion B2 may extend in the direction opposite to the second direction II. In the plane defined by the first direction I and the second direction II, the first bending portion B1 may have a C shape of which one side is opened, and the second bending portion B2 may have a C shape of which the other side is opened. Two contact plugs CT12 and CT13 surrounded by the first bending portion B1 may be connected to different gate lines GL12 and GL13, respectively, and may be adjacent to each other in the first direction I. Two contact plugs CT21 and CT22 surrounded by the second bending portion B2 may be connected to different gate lines GL21 and GL22, respectively, and may be adjacent to each other in the first direction I.

The first bending portion B1 and the second bending portion B2 may have different sizes. The first bending portion B1 and the second bending portion B2 included in the first slit structure SLS1 may have different widths, and the second bending portion B2 may have a greater width than the first bending portion B1. The first bending portion B1 of the second slit structure SLS2 may have a greater width than the first bending portion B1 of the first slit structure SLS1, and may surround the first bending portion B1 of the first slit structure SLS1.

Referring to FIG. 3C, the first gate structure GST1 may include first gate lines GL11 to GL1n stacked in a staircase shape of n layers. The first gate line GL11 of the first layer may include first line portions L11 extending in the first direction I and first pad portions P11 having a greater width than the first line portions L11, and the first line portions L11 and the first pad portions P11 may be alternately arranged. The first gate line GL12 of the second layer may include first line portions L12 extending in the first direction I and first pad portions P12 having a greater width than the first line portions L12, and the first line portions L12 and the first pad portions P12 may be alternately arranged. The first gate line GL13 of the third layer may include a first line portion L13 extending in the first direction I and first pad portions P13 having a greater width than the first line portion L13, and the first line portion L13 and the first pad portions P13 may be alternately arranged. The first gate line GL1n of the n-th layer may include a first line portion L1n extending in the first direction I and a first pad portion P1n having a greater width than the first line portion L1n.

Referring to FIG. 3D, the second gate structure GST2 may include second gate lines GL21 to GL2n stacked in a staircase shape of n layers. The second gate line GL21 of the first layer may include second line portions L21 extending in the first direction I and second pad portions P21 surrounding the first pad portions P11, and the second line portions L21 and the second pad portions P21 may be alternately arranged. The second gate line GL22 of the second layer may include second line portions L22 extending in the first direction I and second pad portions P22 surrounding the first pad portions P12, and the second line portions L22 and the second pad portions P22 may be alternately arranged. The second gate line GL23 of the third layer may include a second line portion L23 extending in the first direction I and second pad portions P23 surrounding the first pad portions P13, and the second line portion L23 and the second pad portions P23 may be alternately arranged. The second gate line GL2n of the n-th layer may include a second line portion L2n extending in the first direction I and a second pad portion P2n surrounding the first pad portion P1n.

The second contact plug CT21 may be connected to a second pad portion P21 located at an end among the second pad portions P21 included in the second gate line GL21. The second pad portion P21 located at the end may be a real pad, and the remaining second pad portions P21 may be dummy pads. The second pad portion P21 may include a first portion P1 extending in the first direction I and a second portion P2 extending in the second direction II. The second contact plug CT21 may be connected to the second portion P2 of the second pad portion P21.

Referring to FIG. 3E, the first conductive layer 31_1 may include first to m-th gate lines GL11 to GLm1. The first to m-th gate lines GL11 to GLm1 may be located at the same layer (e.g., the first layer), and may be arranged in the second direction II.

The first gate line GL11 may include first line portions L11 extending in the first direction I and first pad portions P11 having a greater width than the first line portions L11, and the first line portions L11 and the first pad portions P11 may be alternately arranged. The second gate line GL21 may include second line portions L21 extending in the first direction I and second pad portions P21 surrounding the first pad portions P11, and the second line portions L21 and the second pad portions P21 may be alternately arranged. The third gate line GL31 may include third line portions L31 extending in the first direction I and third pad portions P31 surrounding the second pad portions P21, and the third line portions L31 and the third pad portions P31 may be alternately arranged. The m-th gate line GLm1 may include m-th line portions Lm1 extending in the first direction I and m-th pad portions Pm1 having a greater width than the m-th line portions Lm1, and the m-th line portions Lm1 and the m-th pad portions Pm1 may be alternately arranged. The m-th pad portions Pm1 may be located to correspond to the m−1-th line portions Lm-1.

The second pad portion P21 may surround the first pad portion P11. The first pad portion P11 may have a first width WA, and the second pad portion P21 may have a second width WB greater than the first width WA. The third pad portion P31 may surround the second pad portion P21. The second pad portion P21 may have the second width WB, and the third pad portion P31 may have a third width WC greater than the second width WB.

According to the structure described above, widths of the pad portions may be increased in the second direction II using the slit structures SLS1 to SLSm-1 including the bending portions. Accordingly, the width of the pad portion in the second direction II may be increased without increasing a width of the gate structure GST in the second direction II.

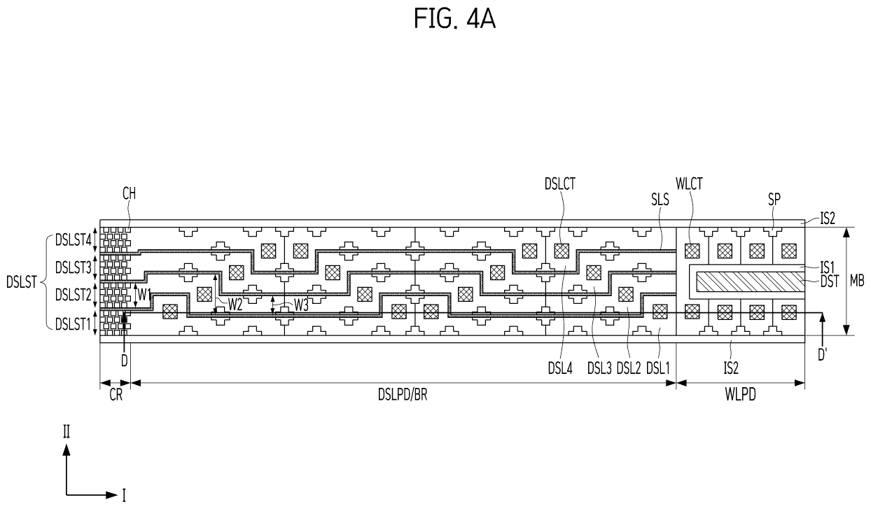

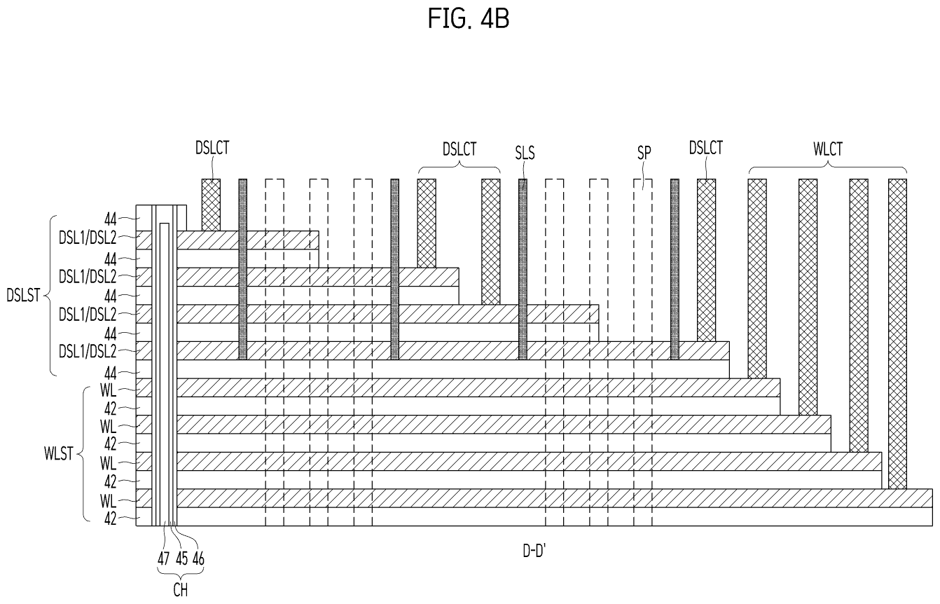

FIGS. 4A and 4B are diagrams illustrating the structure of a semiconductor device in accordance with an embodiment. FIG. 4A is a plan view, and FIG. 4B is a cross-sectional view taken along line D-D′ of FIG. 4A. Hereinafter, the content overlapping with the previously described content may be omitted.

Referring to FIGS. 4A and 4B, the semiconductor device may include a word line stack WLST, a DSL stack DSLST, a slit structure SLS, a DSL contact plug DSLCT, a channel structure CH, a support SP, a first isolation structure IS1, a second isolation structure IS2, a word line contact plug WLCT, and a dummy stack DST.

The word line stack WLST may include word lines WL and insulating layers 42 that are alternately stacked. The word line stack WLST may include a cell region CR, a buffer region BR, and a word line pad region WLPD. The DSL stack DSLST may be located above the word line stack WLST, and may include drain select lines DSL1 to DSL4 and insulating layers 44 that are alternately stacked.

The channel structures CH may be located in the cell region CR, and may extend through the word line stack WLST and the DSL stack DSLST. The channel structure CH may include a channel layer 45, a memory layer 46 surrounding the channel layer 45, and an insulating core 47 located in the channel layer 45.

The DSL stack DSLST may be separated into a first DSL stack DSLST1, a second DSL stack DSLST2, a third DSL stack DSLST3, and a fourth DSL stack DSLST4 by the slit structure SLS. The first DSL stack DSLST1 may include first drain select lines DSL1 stacked in a staircase shape, the second DSL stack DSLST2 may include second drain select lines DSL2 stacked in a staircase shape, the third DSL stack DSLST3 may include third drain select lines DSL3 stacked in a staircase shape, and the fourth DSL stack DSLST may include fourth drain select lines DSL4 stacked in a staircase shape. The DSL contact plugs DSLCT may be connected to the first to fourth drain select lines DSL1 to DSL4, respectively, in the DSL pad region DSLPD.

Each of the first to fourth drain select lines DSL1 to DSL4 may have a first width W1 in the cell region CR, a second width W2 in a pad portion, and a third width W3 in a line portion. The first width W1 may be greater than the third width W3, and the second width W2 may be greater than the first width W1.

The word line contact plugs WLCT may be connected to the word lines WL, respectively, in the word line pad region WLPD. The dummy stack DST may include first insulating layers and second insulating layers that are alternately stacked. The first isolation structure IS1 may be located in the word line pad region WLPD, and may surround the dummy stack DST. The second isolation structure IS2 may extend from the cell region CR to the word line pad region WLPD via the DSL pad region DSLPD. The slit structure SLS may extend from the cell region CR to the DSL pad region DSLPD, and, in some instances, may not be located in the word line pad region WLPD. The supports SP may be located in the word line pad region WLPD and the DSL pad region DSLPD.

According to the structure described above, the slit structure SLS may include bending portions, and the drain select lines DSL1 to DSL4 may have different widths depending on regions. The drain select lines DSL1 to DSL4 may have the first width W1 in the cell region CR, and may have the second width W2 greater than the first width W1 in the pad portion. Accordingly, an area where the DSL contact plug DSLCT is to be formed may be secured. Because a width of the pad portion increases to the second width W2 but a width of the line portion decreases to the third width W3, a contact area may be secured without increasing a pitch of a memory block MB.

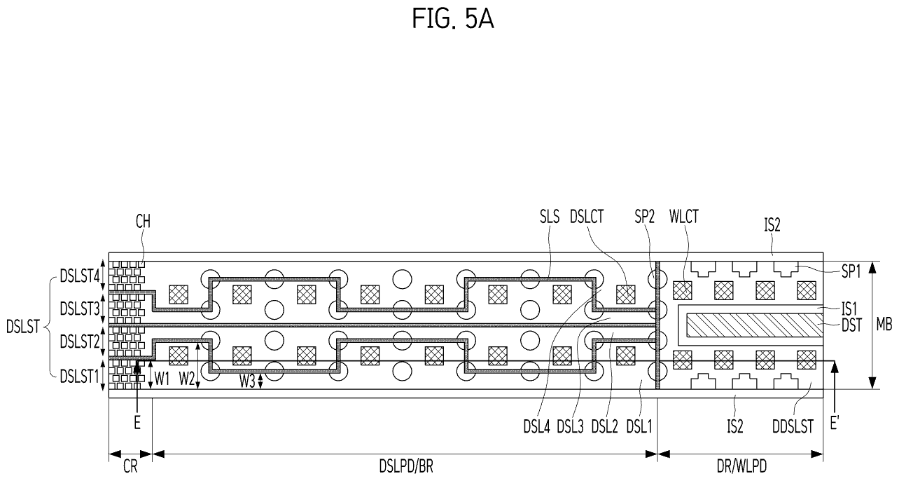

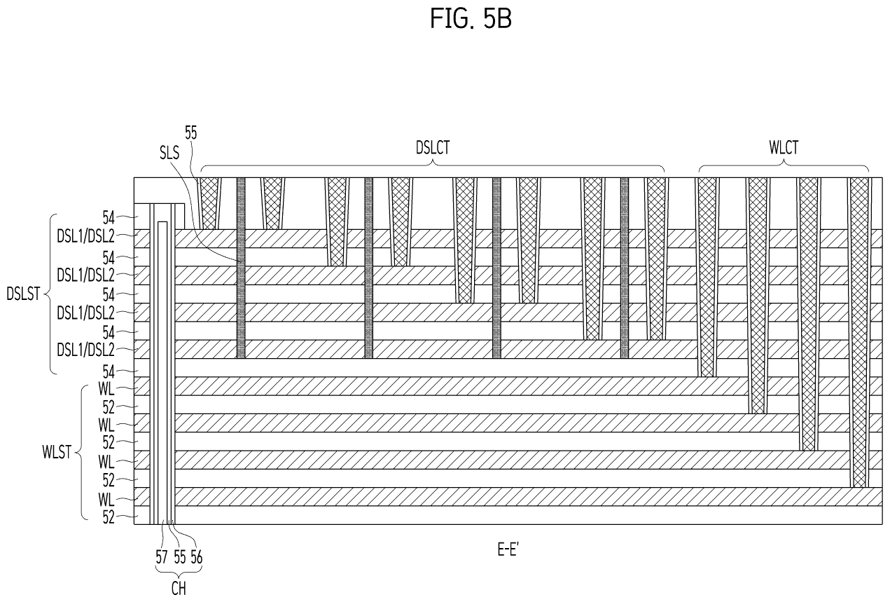

FIGS. 5A and 5B are diagrams illustrating the structure of a semiconductor device in accordance with an embodiment. FIG. 5A is a plan view, and FIG. 5B is a cross-sectional view taken along line E-E′ of FIG. 5A. Hereinafter, the content overlapping with the previously described content may be omitted.

Referring to FIGS. 5A and 5B, the semiconductor device may include a word line stack WLST, a DSL stack DSLST, a slit structure SLS, a DSL contact plug DSLCT, a channel structure CH, a first support SP1, a second support SP2, a first isolation structure IS1, a second isolation structure IS2, a word line contact plug WLCT, and a dummy stack DST.

The word line stack WLST may include word lines WL and insulating layers 52 that are alternately stacked. The word line stack WLST may include a cell region CR, a buffer region BR, and a word line pad region WLPD. The word line stack WLST may have a shape in which an upper surface thereof is flat in the cell region CR, the buffer region BR, and the word line pad region WLPD.

The DSL stack DSLST may be located above the word line stack WLST, and may include drain select lines DSL1 to DSL4 and insulating layers 54 that are alternately stacked. The DSL stack DSLST may include a cell region CR, a DSL pad region DSLPD, and a dummy region DR. The DSL stack DSLST may have a shape in which an upper surface thereof is flat in the cell region CR, the DSL pad region DSLPD, and the dummy region DR. The DSL pad region DSLPD may be located above the buffer region BR, and the dummy region DR may be located above the word line pad region WLPD.

The channel structures CH may be located in the cell region CR, and may extend through the word line stack WLST and the DSL stack DSLST. The channel structure CH may include a channel layer 55, a memory layer 56 surrounding the channel layer 55, and an insulating core 57 located in the channel layer 55.

The DSL stack DSLST may be separated into a first DSL stack DSLST1, a second DSL stack DSLST2, a third DSL stack DSLST3, a fourth DSL stack DSLST4, and a dummy DSL stack DDSLST by the slit structures SLS. The first DSL stack DSLST1 may include first drain select lines DSL1 that are stacked, the second DSL stack DSLST2 may include second drain select lines DSL2 that are stacked, the third DSL stack DSLST3 may include third drain select lines DSL3 that are stacked, and the fourth DSL stack DSLST may include fourth drain select lines DSL4 that are stacked. The DSL contact plugs DSLCT may extend at different depths through the DSL stack DSLST in the DSL pad region DSLPD, and may be connected to the first to fourth drain select lines DSL1 to DSL4, respectively. Sidewalls of the DSL contact plugs DSLCT may be surrounded by insulating spacers 55.

Each of the first to fourth drain select lines DSL1 to DSL4 may have a shape in which pad portions and line portions are repeated in the DSL pad region DSLPD. Each of the first to fourth drain select lines DSL1 to DSL4 may have a first width W1 in the cell region CR, a second width W2 in the pad portion, and a third width W3 in the line portion. The first width W1 may be greater than the third width W3, and the second width W2 may be greater than the first width W1.

The word line contact plugs WLCT may penetrate through the dummy region DR of the DSL stack DSLST and extend into the word line pad region WLPD of the word line stack WLST. The word line contact plugs WLCT may extend at different depths, and may be connected to the word lines WL, respectively.

The first isolation structure IS1 may extend through the dummy region DR of the DSL stack DSLST and the word line pad region WLPD of the word line stack WLST, and may surround the dummy stack DST. The second isolation structure IS2 may extend from the cell region CR to the dummy region DR via the DSL pad region DSLPD.

The slit structure SLS may extend from the cell region CR to the DSL pad region DSLPD. The DSL pad region DSLPD and the dummy region DR may be separated from each other by the slit structure SLS, and the slit structure SLS, in some instances, may not be located in the dummy region DR.

The first supports SP1 may be located in the dummy region DR and the word line pad region WLPD, and may be located between the word line contact plugs WLCT. The second supports SP2 may be located in the DSL pad region DSLPD and the buffer region BR, and may be located between the DSL contact plugs DSLCT. The first supports SP1 and the second supports SP2 may have the same shape or different shapes.

According to the structure described above, the DSL stack DSLST and the word line stack WLST may include a structure different from a staircase structure, and the DSL pad region DSLPD and the word line pad region WLPD may each have a flat upper surface. Because the slit structure SLS includes bending portions, the structure provides the capability to secure a distance between the drain select line contact plug DSLCT and the second support SP2 and to secure an area in which the DSL contact plug DSLCT is to be formed. In addition, a contact area may be secured without increasing a pitch of a memory block MB.

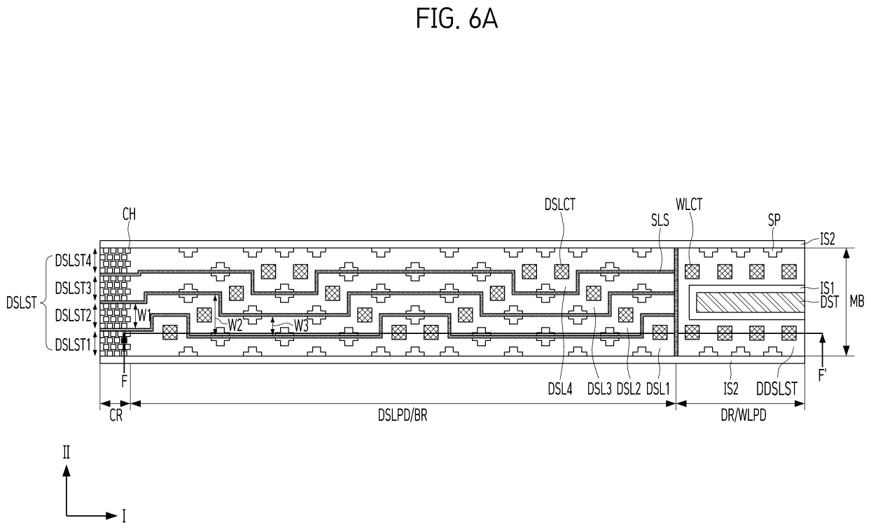

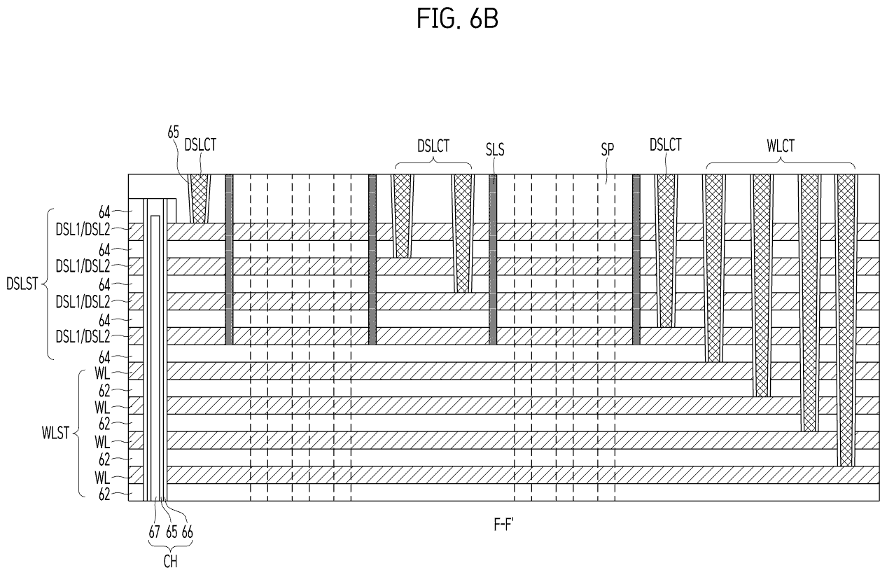

FIGS. 6A and 6B are diagrams illustrating the structure of a semiconductor device in accordance with an embodiment. FIG. 6A is a plan view, and FIG. 6B is a cross-sectional view taken along line F-F′ of FIG. 6A. Hereinafter, the content overlapping with the previously described content may be omitted.

Referring to FIGS. 6A and 6B, the semiconductor device may include a word line stack WLST, a DSL stack DSLST, a slit structure SLS, a DSL contact plug DSLCT, a channel structure CH, a support SP, a first isolation structure IS1, a second isolation structure IS2, a word line contact plug WLCT, and a dummy stack DST.

The word line stack WLST may include word lines WL and insulating layers 62 that are alternately stacked. The word line stack WLST may include a cell region CR, a buffer region BR, and a word line pad region WLPD. The DSL stack DSLST may be located above the word line stack WLST, and may include drain select lines DSL1 to DSL4 and insulating layers 64 that are alternately stacked. The DSL stack DSLST may include a cell region CR, a DSL pad region DSLPD, and a dummy region DR.

The channel structures CH may be located in the cell region CR, and may extend through the word line stack WLST and the DSL stack DSLST. The channel structure CH may include a channel layer 65, a memory layer 66 surrounding the channel layer 65, and an insulating core 67 located in the channel layer 65.

The DSL stack DSLST may be separated into a first DSL stack DSLST1, a second DSL stack DSLST2, a third DSL stack DSLST3, a fourth DSL stack DSLST4, and a dummy DSL stack DDSLST by the slit structure SLS. The DSL pad region DSLPD may include a flat upper surface. The DSL contact plugs DSLCT may extend to different depths in the DSL pad region DSLPD, and may be connected to the first to fourth drain select lines DSL1 to DSL4, respectively. Sidewalls of the DSL contact plugs DSLCT may be surrounded by insulating spacers 65.

Each of the first to fourth drain select lines DSL1 to DSL4 may have a shape in which pad portions and line portions are repeated in the DSL pad region DSLPD. Each of the first to fourth drain select lines DSL1 to DSL4 may have a first width W1 in the cell region CR, a second width W2 in the pad portion, and a third width W3 in the line portion. The first width W1 may be greater than the third width W3, and the second width W2 may be greater than the first width W1.

The word line contact plugs WLCT may penetrate through the DSL stack DSLST, and may extend into the word line stack WLST at different depths. The word line contact plugs WLCT may be connected to the word lines WL, respectively, in the word line pad region WLPD.

The first isolation structure IS1 may extend through the dummy region DR of the DSL stack DSLST and the word line pad region WLPD of the word line stack WLST, and may surround the dummy stack DST. The second isolation structure IS2 may extend from the cell region CR to the dummy region DR via the DSL pad region DSLPD.

The slit structure SLS may extend from the cell region CR to the DSL pad region DSLPD. The DSL pad region DSLPD and the dummy region DR may be separated from each other by the slit structure SLS, and the slit structure SLS, in some instances, may not be located in the dummy region DR. The supports SP may be located in the word line pad region WLPD and the DSL pad region DSLPD.

Further to the structure described hereinabove, the slit structure SLS may include bending portions, and the drain select lines DSL1 to DSL4 may have different widths depending on regions. Accordingly, an area in which the DSL contact plug DSLCT is to be formed may be secured, and a contact area may be secured without increasing a pitch of a memory block MB.

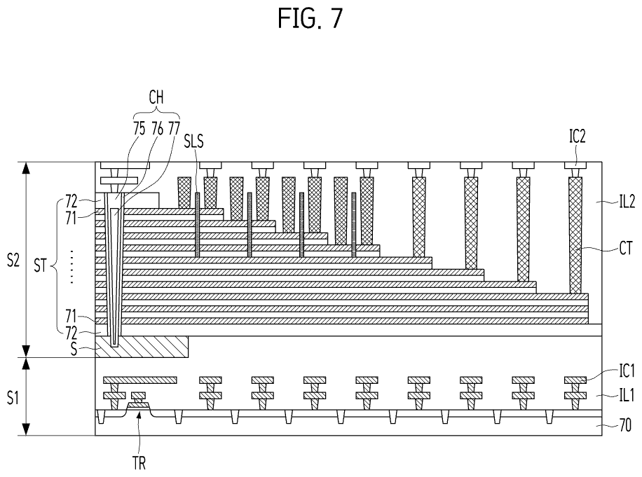

FIG. 7 is a diagram illustrating the structure of a semiconductor device in accordance with an embodiment. Hereinafter, content overlapping with the previously described content may be omitted.

Referring to FIG. 7, the semiconductor device may include a first semiconductor structure S1 and a second semiconductor structure S2. The second semiconductor structure S2 may be located above the first semiconductor structure S1 or the first semiconductor structure S1 may be located above the second semiconductor structure S2.

The first semiconductor structure S1 may include a peripheral circuit PC. The peripheral circuit PC may include a row decoder, a page buffer, an input/output circuit, a logic circuit, and the like. As an example, the first semiconductor structure S1 may include a substrate 70, a transistor TR, a first interconnection structure IC1, and a first interlayer insulating layer IL1. The transistor TR may belong to the peripheral circuit PC. The first interconnection structure IC1 may be formed in the first interlayer insulating layer IL1, and may be electrically connected to the peripheral circuit PC. The first interconnection structure IC1 may include a via, a wiring line, and the like.

The second semiconductor structure S2 may include a memory cell array including stacked memory cells. As an example, the second semiconductor structure S2 may include a source structure S, a stack ST, a channel structure CH, a slit structure SLS, a contact plug CT, a second interconnection structure IC2, and a second interlayer insulating layer IL2.

The stack ST may be located above the source structure S. The stack ST may include conductive layers 71 and insulating layers 72 that are alternately stacked. The stack ST may include a word line stack, a DSL stack, and/or an SSL stack. The conductive layers 71 may be gate lines, and may be word lines, drain select lines, or source select lines. The contact plugs CT may be word line contact plugs or DSL contact plugs. The channel structure CH may include a channel layer 75, a memory layer 76 surrounding the channel layer 75, and an insulating core 77 located in the channel layer 75.

The slit structures SLS may extend through the stack ST, and may have enough depth to penetrate through the drain select lines. The second interconnection structure IC2 may be located in the second interlayer insulating layer IL2, and may be electrically connected to the memory cell array. The second interconnection structure IC2 may include a via, a wiring line, and the like. Although the slit structure SLS and the second interlayer insulating layer IL2 are illustrated as separate layers in FIG. 7, an interface between the slit structure SLS and the second interlayer insulating layer IL2 may not be distinguishable in the actual device.

According to the structure described above, by stacking the first semiconductor structure S1 and the second semiconductor structure S2, the disclosed embodiments may increase the degree of integration of the semiconductor device. In addition, the disclosed embodiments may provide a capability to dispose pad portions of the gate lines in an efficient arrangement or manner using the slit structures SLS including bending portions.

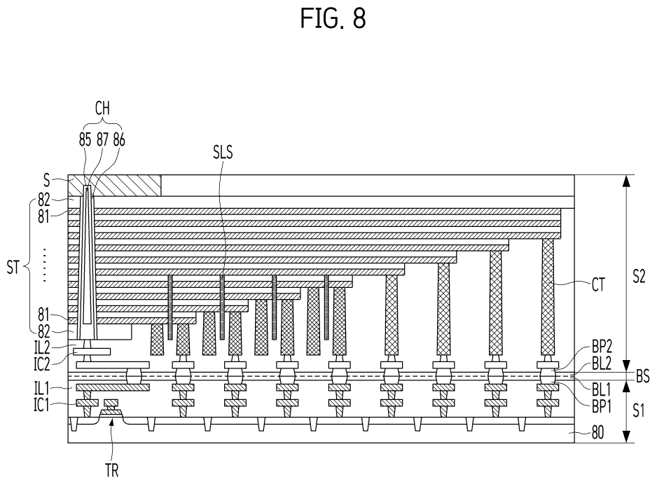

FIG. 8 is a diagram illustrating the structure of a semiconductor device in accordance with an embodiment. Hereinafter, content overlapping with the previously described content may be omitted.

Referring to FIG. 8, the semiconductor device may include a first semiconductor structure S1, a second semiconductor structure S2, and a bonding structure BS. The first semiconductor structure S1 may include a peripheral circuit, and the second semiconductor structure S2 may include a memory cell array.

The first semiconductor structure S1 may include a substrate 80, a transistor TR, a first interlayer insulating layer IL1, and a first interconnection structure IC1. The transistor TR may belong to the peripheral circuit. The first interconnection structure IC1 may be located in the first interlayer insulating layer IL1, and may include a via, a wiring line, and the like. The first interconnection structure IC1 may be electrically connected to the peripheral circuit.

The second semiconductor structure S2 may include a source structure S, a stack ST, a channel structure CH, a slit structure SLS, a contact plug CT, a second interlayer insulating layer IL2, and a second interconnection structure IC2. The stack ST may include conductive layers 81 and insulating layers 82 that are alternately stacked. The source structure S may be located above or below the stack ST. The channel structure CH may include a channel layer 85, a memory layer 86 surrounding the channel layer 85, and an insulating core 87 located in the channel layer 85.

The slit structures SLS may extend through the stack ST, and may have a depth enough to penetrate through the drain select lines. The second interconnection structure IC2 may be located in the second interlayer insulating layer IL2, and may be electrically connected to the memory cell array. The second interconnection structure IC2 may include a via, a wiring line, and the like. Although the slit structure SLS and the second interlayer insulating layer IL2 are illustrated as separate layers in FIG. 8, an interface between the slit structure SLS and the second interlayer insulating layer IL2 may not be distinguishable in the actual device.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array including the stack ST and the peripheral circuit may be electrically connected to each other by the bonding structure BS.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include silicon carbon nitride (SiCN), tetraethyl orthosilicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

According to the structure described above, the first semiconductor structure S1 and the second semiconductor structure S2 are bonded to each other in a vertical direction, and therefore the embodiment may increase the degree of integration of the semiconductor device. In addition, the disclosed embodiments may provide a capability to dispose pad portions of the gate lines in an efficient arrangement or manner using the slit structures SLS including bending portions.

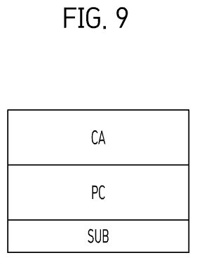

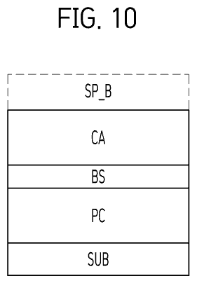

The structure and the manufacturing method according to the above-described embodiments may be applied to semiconductor devices of various structures. FIGS. 9 and 10 illustrate schematic configuration of semiconductor devices to which the above-described embodiments are applicable.

FIG. 9 is a configuration diagram of a semiconductor device according to an embodiment of the present disclosure.

Referring to FIG. 9, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 10 is a configuration diagram of a semiconductor device according to an embodiment of the present disclosure.

Referring to FIG. 10, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

In an alternate embodiment, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations of the semiconductor device may be implemented, equal to or in a similar manner to those described above with reference to FIG. 9.

Meanwhile, the semiconductor device may have a structure in which the embodiments described above with reference to FIGS. 9 and 10 are combined or may have a partially modified structure. In the embodiment described with reference to FIGS. 9 and 10, positions of the memory cell array CA and the peripheral circuit PC may be changed. At least one memory cell array CA and/or at least one peripheral circuit PC may be additionally bonded to the embodiment described with reference to FIGS. 9 and 10. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including first to n-th conductive layers which are sequentially stacked and extending in a first direction, n being an integer of 2 or more;
first to m−1-th slit structures extending in the first direction through the gate structure and separating each of the first to n-th conductive layers into first to m-th gate lines, m being an integer of 2 or more; and
first to m-th contact plugs respectively connected to the first to m-th gate lines,
wherein at least one of the first to m−1-th slit structures includes a bending portion partially surrounding at least two contact plugs connected to gate lines of different conductive layers, among the first to m-th contact plugs.

2. The semiconductor device of claim 1, wherein at least one of the first to m−1-th slit structures comprises:
a first bending portion extending in a second direction intersecting with the first direction; and
a second bending portion extending in a direction opposite to the second direction.

3. The semiconductor device of claim 1, wherein the at least two contact plugs are partially surrounded by the bending portion, and are adjacent to each other in the first direction.

4. The semiconductor device of claim 1, wherein the first to m-th gate lines are drain select lines.

5. The semiconductor device of claim 1, wherein the first to n-th conductive layers are stacked in a staircase shape.

6. The semiconductor device of claim 1, wherein:
the first and second contact plugs of the first to m-th contact plugs are arranged in a row along the first direction;
the third and fourth contact plugs of the first to m-th contact plugs are arranged in a row along the first direction;
the first contact plug and the fourth contact plug are adjacent to each other in a second direction intersecting with the first direction; and
the second contact plug and the third contact plug are adjacent to each other in the second direction.

7. The semiconductor device of claim 1, wherein the first to fourth contact plugs respectively connected to the first to fourth gate lines of a same conductive layer are located at respective vertices of a quadrangle.

8. The semiconductor device of claim 1, wherein each of odd slit structures of the first to m−1-th slit structures includes a bending portion, and each of even slit structures of the first to m−1-th slit structures does not include a bending portion.

9. The semiconductor device of claim 1, wherein the first slit structure and the third slit structure of the first to m−1-th slit structures have a symmetrical shape based on the second slit structure of the first to m−1-th slit structures.

10. The semiconductor device of claim 1, wherein:
the first gate line of the first conductive layer includes a first line portion extending in the first direction and a first pad portion having a greater width than the first line portion;
the second gate line of the first conductive layer includes a second line portion extending in the first direction and a second pad portion having a greater width than the second line portion;
the first line portion and the second pad portion face each other in a second direction intersecting with the first direction; and
the second line portion and the first pad portion face each other in the second direction.

11. The semiconductor device of claim 1, wherein the first contact plug connected to the first gate line of the first conductive layer and the fourth contact plug connected to the fourth gate line of the first conductive layer are adjacent to each other in a second direction intersecting with the first direction, and
the first to third slit structures extend between the first contact plug and the fourth contact plug.

12. The semiconductor device of claim 11, wherein the second contact plug connected to the second gate line of the first conductive layer and the third contact plug connected to the third gate line of the first conductive layer are adjacent to each other in the second direction, and
the second slit structure extends between the second contact plug and the third contact plug.

13. The semiconductor device of claim 1, wherein a bending portion of the second slit structure of the first to m−1-th slit structures has a greater width than a bending portion of the first slit structure, and partially surrounds the bending portion of the first slit structure.

14. The semiconductor device of claim 1, wherein the first to m-th contact plugs respectively connected to the first to m-th gate lines of the first conductive layer are arranged in a first diagonal direction intersecting with the first direction.

15. The semiconductor device of claim 14, wherein the first to m-th contact plugs respectively connected to the first to m-th gate lines of the second conductive layer of the first to n-th conductive layers are arranged in a second diagonal direction intersecting with the first diagonal direction.

16. The semiconductor device of claim 1, wherein:
the first gate line of the first to m-th gate lines includes a first line portion extending in the first direction and a first pad portion having a greater width than the first line portion; and
the second gate line of the first to m-th gate lines includes a second line portion extending in the first direction and a second pad portion partially surrounding the first pad portion.

17. The semiconductor device of claim 16, wherein the second pad portion includes a first portion extending in the first direction and a second portion extending in a second direction intersecting with the first direction, and
the second contact plug of the first to m-th contact plugs is connected to the second portion.

18. The semiconductor device of claim 1, wherein:
the first slit structure extends between the first contact plug and the second contact plug of the first to m-th contact plugs; and
the second slit structure extends between the second contact plug and the third contact plug of the first to m-th contact plugs.
